(19) United States
(12) Patent Application Publication
(10) Pub. No.: US 2015/0346305 A1
(43) Pub. Date: Dec. 3, 2015

(54) SYSTEM AND METHOD FOR GENERATING A MAGNETIC RESONANCE IMAGE

(71) Applicant: General Electric Company, Schenectady, NY (US)

(72) Inventor: Kevin F. King, Menomonee Falls, WI (US)

(73) Assignee: General Electric Company, Schenectady, NY (US)

(21) Appl. No.: 14/288,772

(22) Filed: May 28, 2014

(51) Int. Cl. G01R 33/561; G01R 33/385; G01R 33/341; G01R 33/3815; G01R 33/48; G01R 33/54

(52) U.S. Cl. CPC G01R 33/5611; G01R 33/4818; G01R 33/546; G01R 33/341; G01R 33/3815; G01R 33/385

(57) ABSTRACT

A method for generating a magnetic resonance (MR) image includes applying a pulse sequence including a quadratic field gradient. A first k-space data set is acquired from each of a plurality of RF coils where each first k-space data set including uniformly undersampled data. A randomly undersampled k-space data set is generated for each RF coil from the first k-space data set. A compressed sensing reconstruction technique is applied to the randomly undersampled k-space data set of each RF coil to generate a second k-space data set for each RF coil where each second k-space data set including uniformly undersampled data. A phase scrambling reconstruction technique is applied to the second k-space data set of each RF coil to generate a low resolution coil image for each RF coil. A MR image is generated by applying a parallel imaging technique to the low resolution coil image and second k-space data set for each RF coil.

### FIELD OF THE INVENTION

The present invention relates generally to a magnetic resonance imaging (MRI) system and in particular to a system and method for generating magnetic resonance images using compressed sensing, parallel imaging and phase scrambling.

### BACKGROUND OF THE INVENTION

Magnetic resonance imaging (MRI is a medical imaging modality that can create pictures of the inside of a human body without using x-rays or other ionizing radiation. MRI uses a powerful magnet to create a strong, uniform, static magnetic field (i.e., the “main magnetic field”). When a human body, or part of a human body, is placed in the main magnetic field, the nuclear spins that are associated with the hydrogen nuclei in tissue water become polarized. This means that the magnetic moments that are associated with these spins become preferentially aligned along the direction of the main magnetic field, resulting in a small net tissue magnetization along that axis (the “z axis,” by convention). An MRI system also comprises components called gradient coils that produce smaller amplitude, spatially varying magnetic fields when a current is applied to them. Typically, gradient coils are designed to produce a magnetic field component that is aligned along the z axis, and that varies linearly in amplitude with position along one of the z, y or x axes. The effect of a gradient coil is to create a small ramp on the magnetic field strength, and concomitantly on the resonance frequency of the nuclear spins, along a single axis. Three gradient coils with orthogonal axes are used to “spatially encode” the MR signal by creating a signature resonance frequency at each location in the body. Radio frequency (RF) coils are used to create pulses of RF energy at or near the resonance frequency of the hydrogen nuclei. The RF coils are used to add energy to the nuclear spin system in a controlled fashion. As the nuclear spins then relax back to their rest energy state, they give up energy in the form of an RF signal. This signal is detected by the MRI system and is transformed into an image using a computer and known reconstruction algorithms.

Various techniques have been developed to accelerate MR data acquisition for an MR scan or examination. One technique that has been developed to accelerate MR data acquisition is commonly referred to as “parallel imaging” or “partial parallel imaging.” In parallel imaging, multiple receive coils acquire data from a region or volume of interest, where the data is undersampled, for example, in a phase-encoding direction so that only a fraction of k-space is acquired in an image scan. Thus, parallel imaging is used to accelerate data acquisition in one or more dimensions by exploiting the spatial dependence of phased array coil sensitivity. Parallel imaging has not only been shown to be successful in reducing scan time, but also reducing image blurring and geometric distortions. Moreover, parallel imaging can be used to improve spatial or temporal resolution as well as provide increased volumetric coverage.

There are several types of parallel imaging (PI) reconstruction methods that have been developed to generate the final, unaliased image from accelerated data. These methods can generally be divided into two categories based on how they treat the reconstruction problem. SENSE-based techniques (Sensitivity Encoding) estimate coil sensitivity profiles from low resolution calibration images, which can then be used to unwrap aliased pixels in image space using a direct inversion algorithm. The SENSE-based techniques separately transform the undersampled individual receiver coil k-space data sets into image space resulting in spatially aliased images. Typically, the aliased images are then combined using weights constructed from measured spatial sensitivity profiles from individual coils to give a final image with the aliasing artifacts removed. Autocalibrating PI-based methods, such as GRAPPA (Generalized Auto-Calibrating Partial Parallel Acquisition) and ARC (Autocalibrating Reconstruction for Cartesian Sampling) calculate reconstruction weights (or coefficients)necessary to synthesize unacquired data directly from acquired data using an algorithm that does not require coil sensitivity estimates. Typically, the reconstruction weights or coefficients for autocalibrating PI-based methods are calculated from a small amount of fully sampled calibration data that is typically embedded within the scan, but can also be acquired before or after the scan.

Another technique for accelerating MR data acquisition is known as “compressed sensing.” Compressed sensing originates from the observation that most medical images have some degree of “compressibility.” That is, when transformed into some suitable domain such as a wavelet domain, a substantial number of values can be set to zero (i.e., compressed) with little loss of image quality. In compressed sensing, compressed images are reconstructed using a non-linear reconstruction scheme, such as an L1-norm constraint, wherein the undersampled artifacts in the chosen domain must be sufficiently sparse (or incoherent) to effectively reconstruct the image. Like parallel imaging, compressed sensing has been found to reduce scan time, image blurring and geometric distortion. Yet another technique for accelerating MR data acquisition is known as “phase scrambling” (PS). Phase scrambling is an acceleration method in which a quadratic field is turned on during the acquisition to spread the spectrum of k-space. In the phase scrambling method, k-space can be undersampled and a low resolution image can then be reconstructed without aliasing.

It would be desirable to provide a system and method for generating a MR image that combines parallel imaging, compressed sensing and phase scrambling to provide faster scanning, greater spatial resolution and higher spatial coverage.

### BRIEF DESCRIPTION OF THE INVENTION

In accordance with an embodiment, a method for generating a magnetic resonance (MR) image includes applying a pulse sequence including a quadratic field gradient, acquiring a first k-space data set from each of a plurality of RF coils, each first k-space data set including uniformly undersampled data, generating a randomly undersampled k-space data set for each RF coil from the first k-space data set, applying a compressed sensing reconstruction technique to the randomly undersampled k-space data set of each RF coil to generate a second k-space data set for each RF coil, each second k-space data set including uniformly undersampled data, applying a phase scrambling reconstruction technique to the second k-space data set of each RF coil to generate a low resolution coil image for each RF coil and generating a MR image by applying a parallel imaging technique to the low resolution coil image and second k-space data set for each RF coil.

In accordance with another embodiment, a magnetic resonance (MR) imaging system includes a resonance assembly comprising a magnet, a plurality of gradient coils a plurality of radio frequency (RF) coils and at least one active shim coil, an RF transceiver system coupled to the plurality of RF coils and configured to receive MR data from the plurality of RF coils and a controller coupled to the resonance assembly and the RF transceiver system and programmed to apply a pulse sequence including a quadratic field gradient, acquire a first k-space data set from each of the plurality of RF coils, each first k-space data set including uniformly undersampled data, generate a randomly undersampled k-space data set for each RF coil from the first k-space data set, apply a compressed sensing reconstruction technique to the randomly undersampled k-space data set of each RF coil to generate a second k-space data set for each RF coil, each second k-space data set including uniformly undersampled data, apply a phase scrambling reconstruction technique to the second k-space data set of each RF coil to generate a low resolution coil image for each RF coil, and generate a MR image by applying a parallel imaging technique to the low resolution coil image and second k-space data set for each RF coil.

In accordance with another embodiment, a non-transitory computer readable storage medium having computer executable instructions for performing a method for generating a magnetic resonance (MR) image includes program code for applying a pulse sequence including a quadratic field gradient, program code for acquiring a first k-space data set from each of a plurality of RF coils, each first k-space data set including uniformly undersampled data, program code for generating a randomly undersampled k-space data set for each RF coil from the first k-space data set, program code for applying a compressed sensing reconstruction technique to the randomly undersampled k-space data set of each RF coil to generate a second k-space data set for each RF coil, each second k-space data set including uniformly undersampled data, program code for applying a phase scrambling reconstruction technique to the second k-space data set of each RF coil to generate a low resolution coil image for each RF coil, and program code for generating a MR image by applying a parallel imaging technique to the low resolution coil image and second k-space data set for each RF coil.

### BRIEF DESCRIPTION OF THE DRAWINGS

The invention will become more fully understood from the following detailed description, taken in conjunction with the accompanying drawings, wherein the reference numerals refer to like parts in which:

FIG. 1 is a schematic block diagram of an exemplary magnetic resonance imaging (MRI) system in accordance with an embodiment;

FIG. 2 is a schematic side elevation view of an exemplary magnet assembly in accordance with an embodiment;

FIG. 3 is a schematic diagram of an exemplary RF coil array useful in a parallel imaging in accordance with an embodiment;

FIG. 4 illustrates a method for generating a magnetic resonance image in accordance with an embodiment;

FIG. 5 shows an exemplary pulse sequence including a quadratic field gradient in accordance with an embodiment;

FIG. 6 shows an exemplary uniformly undersampled k-space in accordance with an embodiment;

FIG. 7 shows an exemplary randomly undersampled k-space in accordance with an embodiment;

FIG. 8 shows an exemplary uniformly samples k-space generated by a compressed sensing method in accordance with an embodiment;

FIG. 9 illustrates an exemplary reconstruction process in accordance with an embodiment; and

FIG. 10 illustrates an exemplary reconstruction process in accordance with an embodiment.

### DETAILED DESCRIPTION

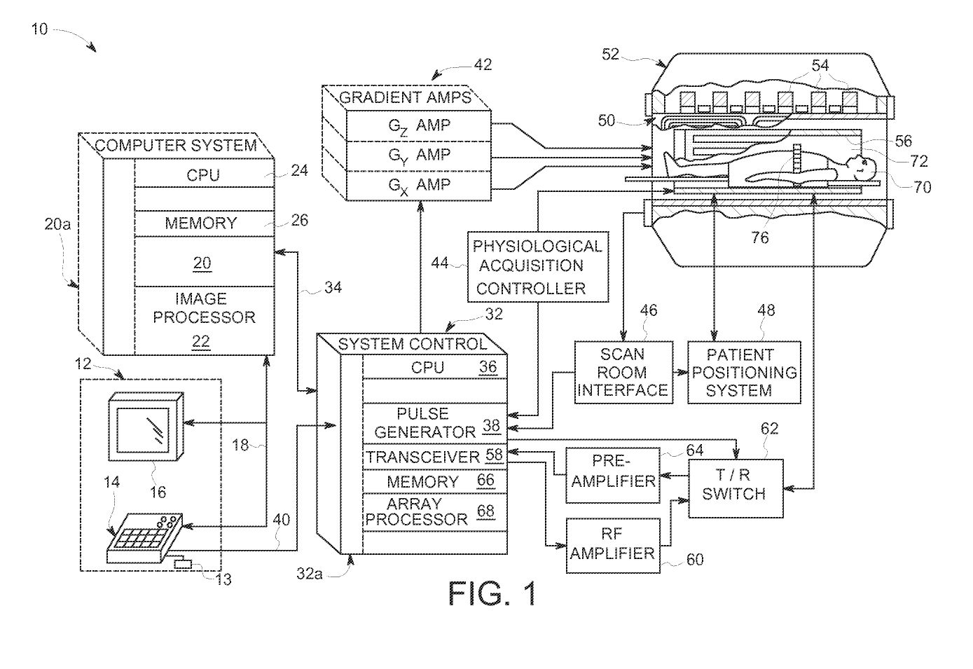

FIG. 1 is a schematic block diagram of an exemplary magnetic resonance imaging (MRI) system in accordance with an embodiment. The operation of MRI system 10 is controlled from an operator console 12 that includes a keyboard or other input device 13, a control panel 14, and a display 16. The console 12 communicates through a link 18 with a computer system 20 and provides an interface for an operator to prescribe MRI scans, display resultant images, perform image processing on the images, and archive data and images. The computer system 20 includes a number of modules that communicate with each other through electrical and/or data connections, for example, such as are provided by using a backplane 20a. Data connections may be direct wired links or may be fiber optic connections or wireless communication links or the like. The modules of the computer system 20 include an image processor module 22, a CPU module 24 and a memory module 26 which may include a frame buffer for storing image data arrays. In an alternative embodiment, the image processor module 22 may be replaced by image processing functionality on the CPU module 24. The computer system 20 is linked to archival media devices, permanent or back-up memory storage or network. Computer system 20 may also communicate with a separate system control computer 32 through a link 34. The input device 13 can include a mouse, joystick, keyboard, track ball, touch activated screen, light wand, voice control, or any similar or equivalent input device, and may be used for interactive geometry prescription.

The system control computer 32 includes a set of modules in communication with each other via electrical and/or data connection 32a. Data connections 32a may be direct wired links, or may be fiber optic connections or wireless communication links or the like. In alternative embodiments, the modules of computer system 20 and system control computer 32 may be implemented on the same computer system or a plurality of computer systems. The modules of system control computer 32 include a CPU module 36 and a pulse generator module 38 that connects to the operator console 12 through a communication link 40. The pulse generator module 38 may alternatively be integrated into the scanner equipment (e.g., resonance assembly 52). It is through link 40 that the system control computer 32 receives commands from the operator to indicate the scan sequence that is to be performed. The pulse generator module 38 operated the system components that play out (i.e., perform) the desired pulse sequence by sending instructions, commands and/or requests describing the timing, strength and shape of the RF pulses and pulse sequences to be produced and the timing and length of the data acquisition window. The pulse generator module 38 connects to a gradient amplifier system 42 and produces data called gradient waveforms that control the timing and shape of the gradient pulses that are to be used during the scan. The pulse generator module 38 may also receive patient data from a physiological acquisition controller 44 that receives signals from a number of different sensors connected to the patient, such as ECG signals from electrodes attached to the patient. The pulse generator module 38 connects to a scan room interface circuit 46 that receives signals from various sensors associated with the condition of the patient and the magnet system. It is also through the scan room interface circuit 46 that a patient positioning system 48 receives commands to move the patient table to the desired position for the scan.

The gradient waveforms produced by the pulse generator module 38 are applied to gradient amplifier system 42 which is comprised of Gₓ, G_{y} and G_{z} amplifiers. Each gradient amplifier excites a corresponding physical gradient coil in a gradient coil assembly generally designated 50 to produce the magnetic field gradient pulses used for spatially encoding acquired signals. The gradient coil assembly 50 forms part of a resonance assembly 52 that includes a polarizing superconducting magnet with superconducting main coils 54. Resonance assembly 52 may include a whole-body RF coil 56, surface or parallel imaging coils 76 or both. The coils 56, 76 of the RF coil assembly may be configured for both transmitting and receiving or for transmit-only or receive-only. A patient or imaging subject 70 may be positioned within a cylindrical patient imaging volume 72 of the resonance assembly 52. A transceiver module 58 in the system control computer 32 produces pulses that are amplified by an RF amplifier 60 and coupled to the RF coils 56, 76 by a transmit/receive switch 62. The resulting signals emitted by the excited nuclei in the patient may be sensed by the same RF coil 56 and coupled through the transmit/receive switch 62 to a preamplifier 64. Alternatively, the signals emitted by the excited nuclei may be sensed by separate receive coils such as parallel or surface coils 76. The amplified MR signals are demodulated, filtered and digitized in the receiver section of the transceiver 58. The transmit/receive switch 62 is controlled by a signal from the pulse generator module 38 to electrically connect the RF amplifier 60 to the RF coil 56 during the transmit mode and to connect the preamplifier 64 to the RF coil 56 during the receive mode. The transmit/receive switch 62 can also enable a separate RF coil (for example, a parallel or surface coil 76) to be used in either the transmit or receive mode.

The MR signals sensed by the RF coil 56 or parallel or surface coil 76 are digitized by the transceiver module 58 and transferred to a memory module 66 in the system control computer 32. Typically, frames of data corresponding to MR signals are stored temporarily in the memory module 66 until they are subsequently transformed to create images. An array processor 68 uses a known transformation method, most commonly a Fourier transform, to create images from the MR signals. These images are communicated through the link 34 to the computer system 20 where it is stored in memory. In response to commands receive from the operator console 12 this image data may be archived in long term storage or it may be further processed by the image processor 22 and conveyed to the operator console 12 and presented on display 16.

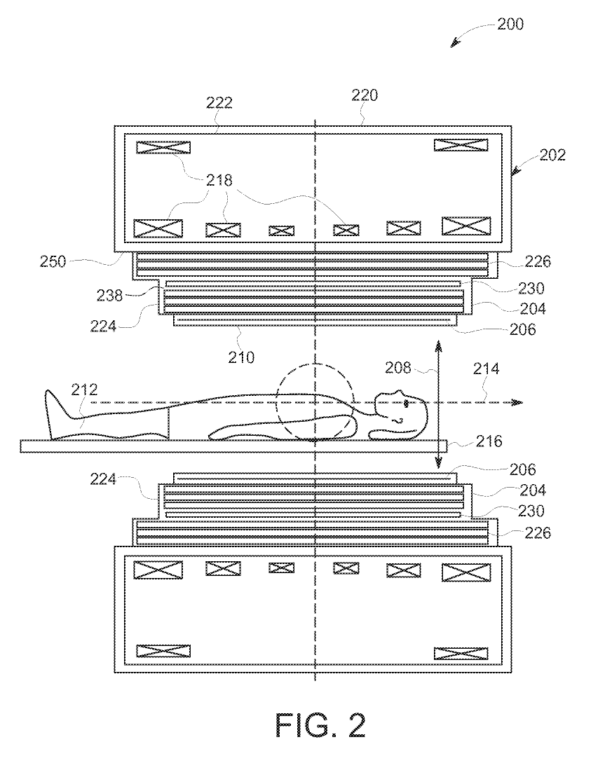

FIG. 2 is a schematic side elevation view of an exemplary magnet assembly in accordance with an embodiment. Magnet assembly 200 may be used in a resonance assembly such as resonance assembly 52 of MRI system 10 shown in FIG. 1. Magnet assembly 200 is cylindrical in shape and includes, among other elements, a superconducting magnet 202, a gradient coil assembly 204 and an RF coil 206. Various other elements, such as covers, supports, suspension members, end caps, brackets, etc. are omitted from FIG. 2 for clarity. A cylindrical patient volume or bore 208 is surrounded by a patient bore tube 210. RF coil 206 is cylindrical and is disposed around an outer surface of the patient bore tube 210 and mounted inside the cylindrical gradient coil assembly 204. The gradient coil assembly 204 is disposed around the RF coil 206 in a spaced-apart coaxial relationship and the gradient coil assembly 204 circumferentially surrounds the RF coil 206. Gradient coil assembly 204 is mounted inside magnet 202 and is circumferentially surrounded by magnet 202.

A patient or imaging subject 212 may be inserted into the magnet assembly 200 along a center axis 214 (e.g., a z-axis) on a patient table or cradle 216. Center axis 214 is aligned along the tube axis of the magnet assembly 200 parallel to the direction of a main magnetic field, BO, generated by the magnet 202. RF coil 206 may be used to apply a radio frequency pulse (or a plurality of pulses) to a patient or subject 212 and may be used to receive MR information back from the subject 212. Gradient coil assembly 204 generates time dependent gradient magnetic pulses that are used to spatially encode points in the imaging volume.

Superconducting magnet 202 may include, for example, several radially aligned and longitudinally spaced apart superconductive coils 218, each capable of carrying a large current. The superconductive coils 218 are designed to create a magnetic field, BO, within the patient volume 208. The superconductive coils 218 are enclosed in a cryogenic environment within a cryostat 222. The cryogenic environment is designed to maintain the temperature of the superconducting coils 218 below the appropriate critical temperature so that the superconducting coils 218 are in a superconducting state with zero resistance. Cryostat 222 may include, for example, a helium vessel (not shown) and thermal or cold shields (not shown) for containing and cooling magnet windings in a known manner. Superconducting magnet 202 is enclosed by a magnet vessel 220, e.g., a cryostat vessel. Magnet vessel 220 is configured to maintain a vacuum and to prevent heat from being transferred to the cryogenic environment.

Gradient coil assembly 204 may be a self-shielded gradient coil assembly. Gradient coil assembly 204 comprises a cylindrical inner gradient coil assembly or winding 224 and a cylindrical outer gradient coil assembly or winding 226 disposed in concentric arrangement with respect to a common axis 214. Inner gradient coil assembly 224 includes X-, Y- and Z-gradient coil and outer gradient coil assembly 226 includes the respective outer X-, Y- and Z-gradient coils. The coils of gradient coil assembly 204 may be activated by passing an electric current through the coils to generate a gradient field in the patient volume 208 as required in MR imaging. A warm bore is defined by an inner cylindrical surface of a magnet vessel 220.

Magnet assembly 200 may also include active shim coils 230 that are configured to provide compensation (e.g., compensating magnetic fields) for inhomogeneities in the main magnetic field, BO. The active shim coils 230 may include, for example, second order or higher shim coils. In FIG. 2, the active shim coils 230 are shown located at a radius inside the gradient col assembly 204. Active shim coils 230 are positioned in a volume or space 238 between the inner gradient coil assembly 224 and the outer gradient coil assembly 226. In an alternative embodiment, the shim coils 230 may be positioned at a radius within the magnet assembly 200 between the warm bore 250 and the gradient coil assembly 204. In other embodiments, the active shim coils 230 may be located at other positions within the magnet assembly 200 as known in the art.

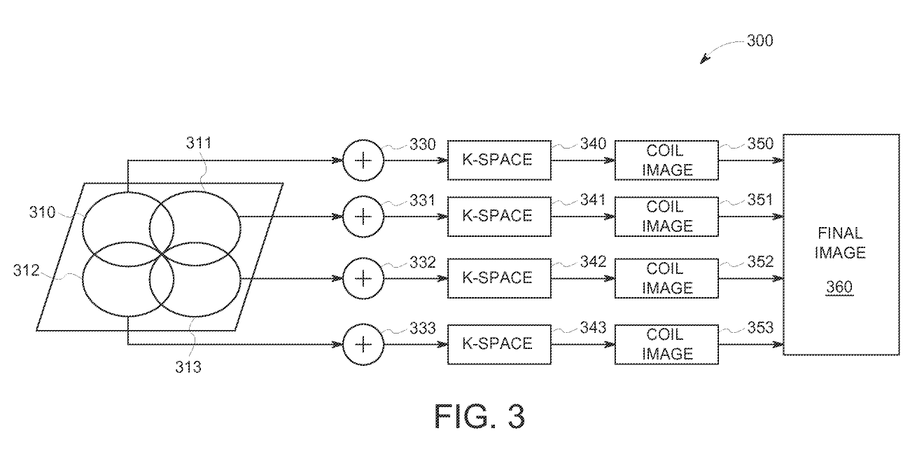

As mentioned, the MRI system 10 may include parallel imaging coils 76. FIG. 3 is a schematic diagram of an exemplary RF coil array useful in a parallel imaging technique in accordance with an embodiment. An array of RF receiver coil elements 300 is used to acquire MRI data for a field-of-view (FOV) in a subject and includes four separate RF receiver coil elements 310, 311, 312, 313. It is contemplated, however, that the coil array 300 may include more or less than four coil elements. One skilled in the art will appreciate that the array illustrated in FIG. 3 is exemplary and many other receiver coil geometries may be used in accordance with embodiments. Each RF receiver coil element 310, 311, 312, 313 receives sufficient MRI signals to reconstruct an image from the FOV. MRI signals from each RF receiver coil element 310, 311, 312, 313 are transmitted separately to a corresponding data acquisition channel 330, 331, 332, 333, respectively. The MRI signals from ach data acquisition channel are used to fill a corresponding (and separate) k-space 340, 341, 342, 343. A separate “coil image” 350, 351, 352, 353 is constructed from each k-space 340, 241, 242, 343. The separate coil images 350, 351, 352, 353 may then be combined using any one of the summation techniques known in the art (e.g., sum of squares) into the final composite image 360.

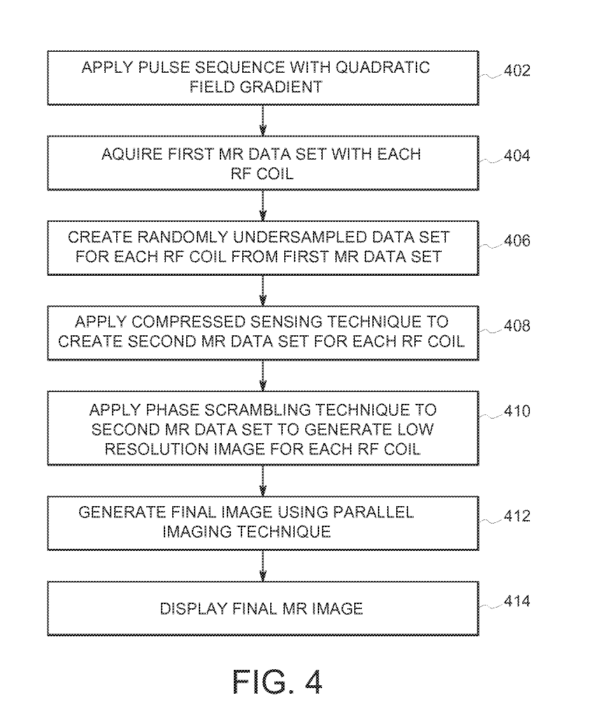

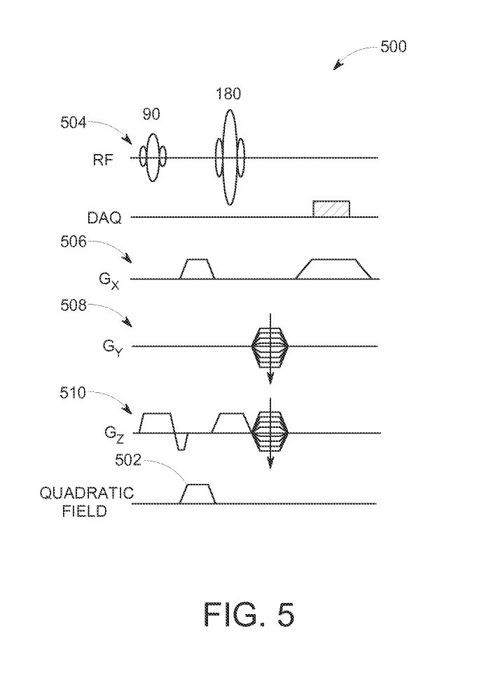

FIG. 4 illustrates a method for generating a magnetic resonance image in accordance with an embodiment. At block 402, a pulse sequence is applied to a patient or subject using the RF coils and gradient coils of a magnetic resonance imaging systems such as RF coils 56, 76 and gradient coil assembly 50 shown in FIG. 1. The pulse sequence includes a quadratic field gradient for phase scrambling. FIG. 5 illustrates an exemplary pulse sequence with a quadratic field gradient in accordance with an embodiment. The pulse sequence 500 is an exemplary three dimensional (3D) spin echo pulse sequence. It should be understood that the systems and methods described herein may be used with other types of pulse sequences. RF excitation and RF refocusing pulses are shown along an RF axis 504. Frequency encoding (or readout) gradients are shown along a frequency encode (or readout) gradient axis 506 (e.g. an x-axis). Phase encoding gradients are shown along a phase encode gradient axis 508 (e.g. a y-axis). Slice select gradients are shown along a slice select gradient axis 510 (e.g. a z-axis). A quadratic field gradient 502 is applied during the acquisition to spread the spectrum in k-space. In one embodiment, the quadratic field gradient is turned on after an RF excitation pulse and is turned off before readout during each repetition period (TR). The quadratic field gradient 502 may be generated using an active shim coil in an MRI system such as, for example, active shim coil 230 shown in FIG. 2. In an another embodiment, a separate coil may be provided in a magnetic resonance imaging system and used to generate the quadratic field gradient 502.

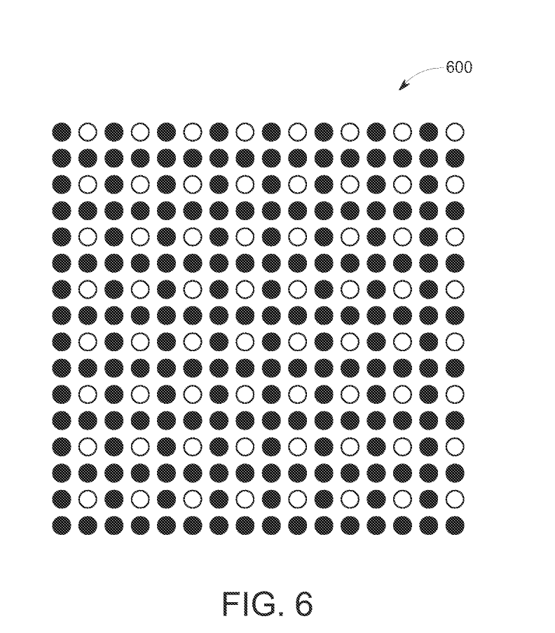

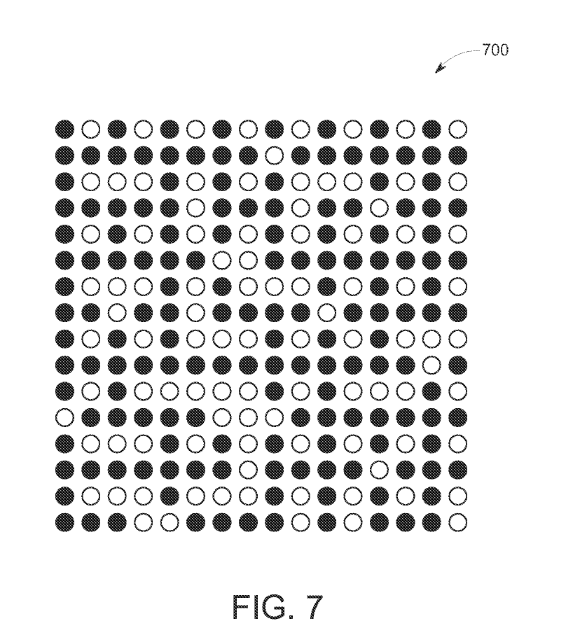

Returning to FIG. 4, at block 404, a first set of MR data is acquired using each RF coil in a plurality of RF coils, such as, for example, RF coil array 300 shown in FIG. 3. The first set of MR data for each RF coil is acquired using a uniformly undersampled k-space sampling pattern. FIG. 6 shows an exemplary uniformly undersampled k-space 600. The undersampling factor may be based on the desired parallel imaging acceleration. At block 406 of FIG. 4, for each RF coil a randomly undersampled k-space data set is created from the first MR data set. The sampling pattern for the randomly undersampled k-space data set may be one known in the art for use with compressed sensing methods, for example a Gaussian sampling patter or a variable density Poisson disk sampling patter. FIG. 7 shows an exemplary randomly undersampled k-space 700.

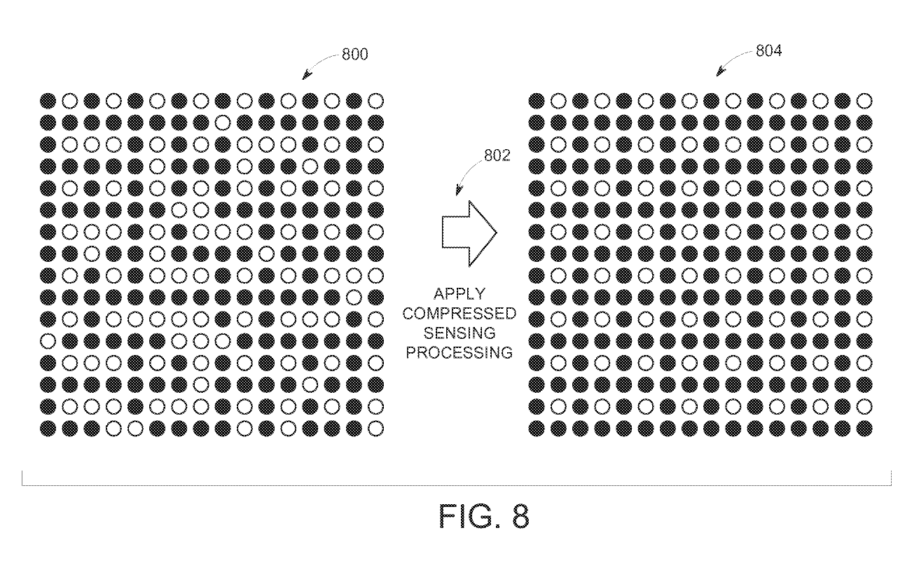

At block 408 of FIG. 4, a compressed sensing technique 802s applied to the randomly undersampled k-space 800 for each RF coil to generate a second MR data set 804 for each RF coil as shown in FIG. 8. The second MR data set 804 for each RF coil is a uniformly undersampled k-space data set. Any compressed sensing technique known in the art may be used to fill in the uniformly undersampled k-space 804 from the randomly undersampled k-space 800 in accordance with embodiments. For example, techniques such as the sparseMRI algorithm or the ESPIRiT algorithm may be used. In one embodiment, the compressed sensing technique is applied to the randomly undersampled k-space 800 for each RF coil to reconstruct an aliased image for each RF coil. The aliased image generated for each RF coil corresponds to a uniformly undersampled k-space data set. A Fourier transform is then applied to each aliased image to generate a uniformly undersampled k-space data set 804 for each RF coil.

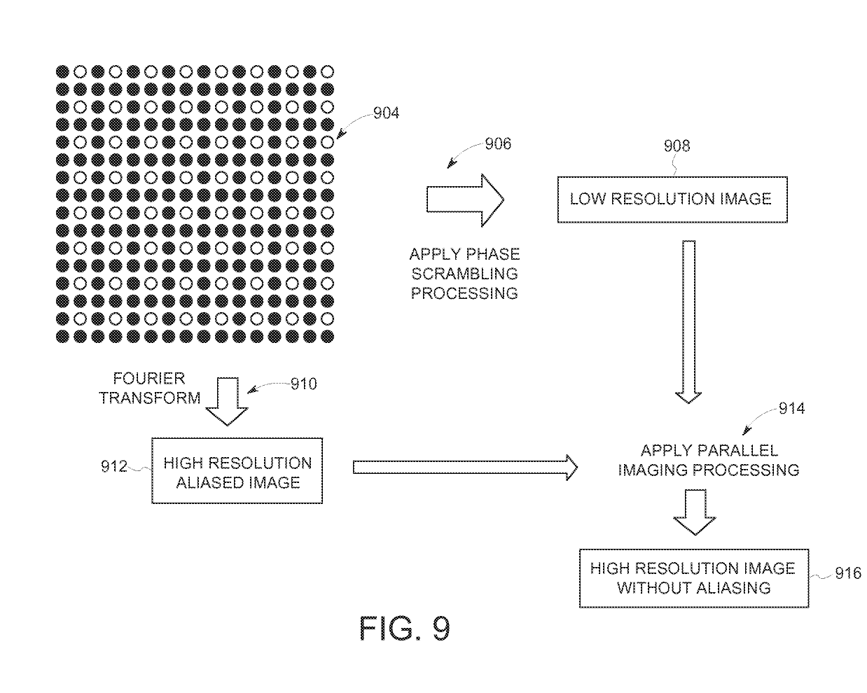

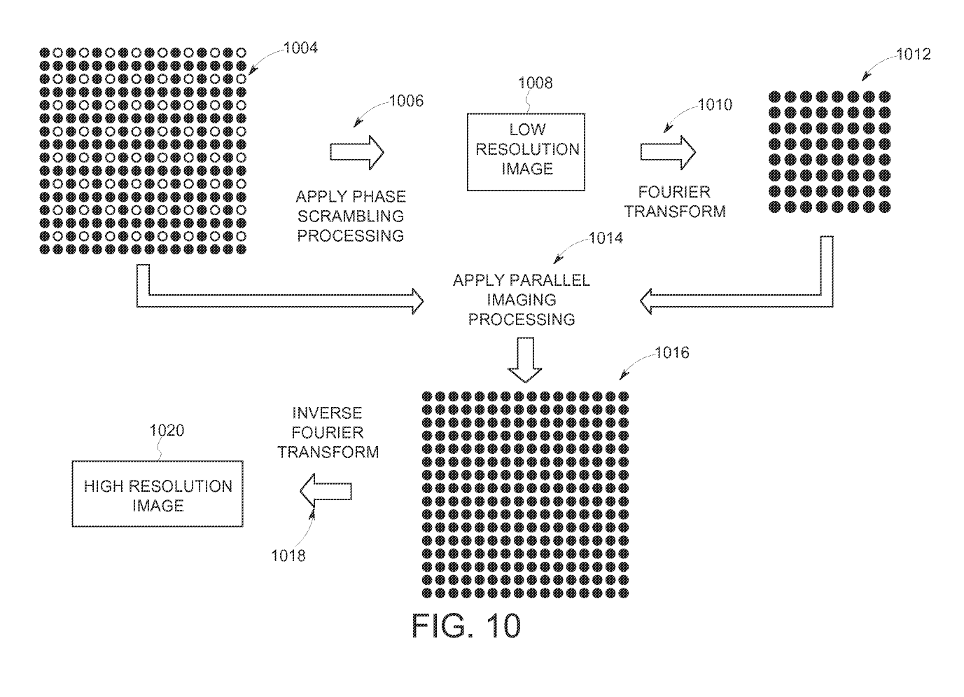

Returning to FIG. 4, blocks 410 to 414 will be discussed together with reference to FIGS. 9 and 10. At block 410, a phase scrambling technique 906, 1006 is applied to the second MR data set 904, 1004 if each RF coil to generate a low resolution coil image 908, 1008 for each RF coil. Any known phase scrambling reconstruction technique may be used. In one embodiment, the phase scrambling technique 906 is used on a center section of the uniformly undersampled k-space 904, 1004 to create the low resolution image for each RF coil. At block 412, a final image is generated using a parallel imaging technique. Known parallel imaging techniques such as SENSE-based techniques or autocalibrating techniques may be used to reconstruct the final image. At block 414, the final image may be displayed on, for example, a display 16 in the MR system as shown in FIG. 1.

FIG. 9 illustrates an exemplary reconstruction process using a SENSE-based parallel imaging technique in accordance with an embodiment. In FIG. 9, a Fourier transform 910 is applied to the second MR data set 904 of each RF coil to generate a high resolution aliased image 912 for each RF coil. The low resolution image 908 for each RF coil is used to provide a coil sensitivity profile or map for each RF coil. The coil sensitivity profiles are used by SENSE-based parallel imaging processing 914 that is applied to the high resolution aliased coil images 912 to generate a final image 914. The final image 914 is a high resolution image without aliasing.

FIG. 10 illustrates an exemplary reconstruction process using an autocalibrating parallel imaging technique in accordance with an embodiment. In FIG. 10, the low resolution image 1008 for each RF coil are used to obtain k-space data that may be used to calculate unaliasing coefficients (or reconstruction kernels). In particular, a Fourier transform 1010 is applied to the low resolution image 1008 to create low resolution k-space data 1012. In one embodiment, a small amount (e.g., from a center region) of fully sampled data (i.e., calibration data) from the low resolution k-space data is used to calculate the unaliasing coefficients for the parallel imaging method. Parallel imaging processing 1014 is used to synthesize unacquired k-space data using the unaliasing coefficients and MR data from the second MR data set 1004 of each RF coil. For each RF coil, the synthesized data is combined with the data in the undersampled k-space data set 1004 to create a complete (or fully sampled) k-space data set 1016. An inverse Fourier transform 1018 may then be applied to the complete k-space data set 1016 of each RF coil to generate a high resolution coil image 1020 for each RF coil. The coil images for each RF coil may then be combined to generate a final image. The coil images may be combined using known reconstruction techniques such as a sum of squares technique.

Computer-executable instructions for generating a magnetic resonance image according to the above-described method may be stored on a form of computer readable media. Computer readable media includes volatile and nonvolatile, removable, and non-removable media implemented in any method or technology for storage of information such as computer readable instructions, data structures, program modules or other data. Computer readable media includes, but is not limited to, random access memory (RAM), read-only memory (ROM), electrically erasable programmable ROM (EEPROM), flash memory or other memory technology, compact disk ROM (CD-ROM), digital versatile disks (DVD) or other optical storage, magnetic cassettes, magnetic tape, magnetic disk storage or other magnetic storage devices, or any other medium which can be used to store the desired instructions and which may be accessed by system 10 (shown in FIG. 1), including by internet or other computer network form of access.

A technical effect of the disclosed system and method is that is provides for a computer implemented technique for generating a magnetic resonance image.

This written description used examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims. The order and sequence of any process or method steps may be varied or re-sequenced according to alternative embodiments.

Many other changes and modifications may be made to the present invention without departing from the spirit thereof. The scope of these and other changes will become apparent from the appended claims.

We claim:

1. A method for generating a magnetic resonance (MR) image, the method comprising:
applying a pulse sequence including a quadratic field gradient;
acquiring a first k-space data set from each of a plurality of RF coils, each first k-space data set including uniformly undersampled data;
generating a randomly undersampled k-space data set for each RF coil from the first k-space data set;
applying a compressed sensing reconstruction technique to the randomly undersampled k-space data set of each RF coil to generate a second k-space data set for each RF coil, each second k-space data set including uniformly undersampled data;
applying a phase scrambling reconstruction technique to the second k-space data set of each RF coil to generate a low resolution coil image for each RF coil; and
generating a MR image by applying a parallel imaging technique to the low resolution coil image and second k-space data set for each RF coil.

2. A method according to claim 1, wherein applying a compressed sensing reconstruction technique comprises generating an aliased image for each RF coil and applying a Fourier transform to the aliased image of each RF coil to generate the second set of MR data for each RF coil.

3. A method according to claim 1, wherein the phase scrambling reconstruction technique is applied to a center section of the second k-space data set of each RF coil.

4. A method according to claim 1, wherein the parallel imaging technique is a SENSE-based parallel imaging technique.

5. A method according to claim 1, wherein the parallel imaging technique is an autocalibrating parallel imaging technique.

6. A method according to claim 4, wherein applying the parallel imaging technique comprises generating an aliased coil image for each RF coil using the second k-space data set for each RF coil and generating a coil sensitivity profile for each RF coil using the low resolution coil image for each RF coil.

7. A method according to claim 5, wherein applying the parallel imaging technique comprises generating a low resolution k-space data set for each RF coil using the low resolution coil image for each RF coil and calculating a set of unaliasing coefficients for each RF coil using the low resolution k-space data.

8. A method according to claim 7, wherein applying the parallel imaging technique further comprises applying the unaliasing coefficients to the second k-space data set for each RF coil to synthesize unacquired data for each RF coil and combining the second k-space data set and the synthesized data for each RF coil to generate a complete k-space data set for each RF coil.

9. A method according to claim 8, wherein generating a MR image comprises generating a coil image for each RF coil based on the complete k-space data set for the associated RF coil and generating a final image based on the coil images for each RF coil.

10. A magnetic resonance (MR) imaging system comprising:
a resonance assembly comprising a magnet, a plurality of gradient coils a plurality of radio frequency (RF) coils and at least one active shim coil;
an RF transceiver system coupled to the plurality of RF coils and configured to receive MR data from the plurality of RF coils; and
a controller coupled to the resonance assembly and the RF transceiver system and programmed to:
apply a pulse sequence including a quadratic field gradient;
acquire a first k-space data set from each of the plurality of RF coils, each first k-space data set including uniformly undersampled data;
generate a randomly undersampled k-space data set for each RF coil from the first k-space data set;
apply a compressed sensing reconstruction technique to the randomly undersampled k-space data set of each RF coil to generate a second k-space data set for each RF coil, each second k-space data set including uniformly undersampled data;
apply a phase scrambling reconstruction technique to the second k-space data set of each RF coil to generate a low resolution coil image for each RF coil; and
generate a MR image by applying a parallel imaging technique to the low resolution coil image and second k-space data set for each RF coil.

11. A system according to claim 10, wherein applying a compressed sensing reconstruction technique comprises generating an aliased image for each RF coil and applying a Fourier transform to the aliased image of each RF coil to generate the second set of MR data for each RF coil

12. A system according to claim 10, wherein the phase scrambling reconstruction technique is applied to a center section of the second k-space data set of each RF coil

13. A system according to claim 10, wherein the parallel imaging technique is a SENSE-based parallel imaging technique

14. A system according to claim 10, wherein the parallel imaging technique is an autocalibrating parallel imaging technique

15. A system according to claim 13, wherein applying the parallel imaging technique comprises generating an aliased coil image for each RF coil using the second k-space data set for each RF coil and generating a coil sensitivity profile for each RF coil using the low resolution coil image for each RF coil.

16. A system according to claim 14, wherein applying the parallel imaging technique comprises generating a low resolution k-space data set for each RF coil using the low resolution coil image for each RF coil and calculating a set of unaliasing coefficients for each RF coil using the low resolution k-space data.

17. A system according to claim 16, wherein applying the parallel imaging technique further comprises applying the unaliasing coefficients to the second k-space data set for each RF coil to synthesize unacquired data for each RF coil and combining the second k-space data set and the synthesized data for each RF coil to generate a complete k-space data set for each RF coil

18. A system according to claim 17, wherein generating a MR image comprises generating a coil image for each RF coil based on the complete k-space data set for the associated RF coil and generating a final image based on the coil images for each RF coil

19. A non-transitory computer readable storage medium having computer executable instructions for performing a method for generating a magnetic resonance (MR) image, the computer readable storage medium comprising:
program code for applying a pulse sequence including a quadratic field gradient;
program code for acquiring a first k-space data set from each of a plurality of RF coils, each first k-space data set including uniformly undersampled data;
program code for generating a randomly undersampled k-space data set for each RF coil from the first k-space data set;
program code for applying a compressed sensing reconstruction technique to the randomly undersampled k-space data set of each RF coil to generate a second k-space data set for each RF coil, each second k-space data set including uniformly undersampled data;
program code for applying a phase scrambling reconstruction technique to the second k-space data set of each RF coil to generate a low resolution coil image for each RF coil; and
program code for generating a MR image by applying a parallel imaging technique to the low resolution coil image and second k-space data set for each RF coil.
